(19) United States
(12) Patent Application Publication
(10) Pub. No.: US 2026/0182226 A1
(43) Pub. Date: Jun. 25, 2026

(54) DISPLAY DEVICE

(71) Applicant: LG Display Co., Ltd., Seoul (KR)

(72) Inventors: Kyung-Kook JANG, Paju-si (KR); Seung-Bum LEE, Paju-si (KR); Seong-Han HWANG, Paju-si (KR); Won-Rae KIM, Paju-si (KR); Byung-Gwan HYUN, Paju-si (KR)

(73) Assignee: LG Display Co., Ltd., Seoul (KR)

(21) Appl. No.: 19/322,293

(22) Filed: Sep. 8, 2025

(30) Foreign Application Priority Data
Dec. 24, 2024 (KR) 10-2024-0194880

(51) Int. Cl. H10K 59/80; H10H 29/37; H10H 29/855; H10K 59/122

(52) U.S. Cl. CPC H10K 59/879; H10H 29/37; H10H 29/855; H10K 59/122

(57) ABSTRACT

A display device can include an anti-reflection pattern or a column spacer disposed between a light emitting diode and a bank layer, the anti-reflection pattern or column spacer including a blue colorant. The blue light reflected from the anti-reflection pattern or the column spacer is barely perceptible to the human eye, which helps reduce visible stains such as rainbow mura caused by external light reflection. Additionally, blue light emitted from the light emitting diode can pass through the anti-reflection pattern and/or the column spacer, thereby increasing the transmitted light intensity. As a result, image quality can be enhanced while minimizing luminance loss.

### CROSS-REFERENCE TO RELATED APPLICATION

This application claims priority under 35 U.S.C. § 119(a) to the Korean Patent Application No. 10-2024-0194880, filed in the Republic of Korea on Dec. 24, 2024, the entire contents of which are hereby expressly incorporated by reference into the present application.

### BACKGROUND

### Technical Field

The present disclosure relates to a display device, and more particularly to, a display device that can minimize a stain caused by an external light reflection and can emit light with uniform intensity in each sub-pixel area by controlling external light absorption.

### Description of the Related Art

Various display devices for displaying images in TV, a monitor, a smart phone, a tablet PC and a notebook computer have been utilized. The display devices includes a display panel having multiple light emitting elements or liquid crystals for implementing images and transistors for controlling each light emitting element or liquid crystal so that the display devices display desired images through the multiple light emitting element or the liquid crystals.

Technologies for a light emitting display device including a light emitting diode as one of the display devices have been developed rapidly. The light emitting display device can be divided to an organic light emitting display device using organic luminescent materials and an inorganic light emitting display device using inorganic luminescent materials.

The display device includes a polarizing plate on a display surface so as to minimize external light reflection.

### BRIEF SUMMARY

The disclosed display device includes a blue colorant incorporated into either an anti-reflection pattern or a column spacer positioned between the light emitting diode and the surrounding bank layer. This configuration selectively absorbs ambient red and green light, which are most visible to the human eye, while allowing blue light to pass or reflect. As a result, visible artifacts such as rainbow mura are reduced without the use of a polarizing plate. Removing the polarizer maintains emitted luminance, lowers power consumption, and improves mechanical flexibility, making the design suitable for foldable applications.

The anti-reflection pattern or column spacer also functions to expand the effective emission area, particularly in blue sub-pixels where luminous efficiency tends to be lower. This helps compensate for differences in brightness among red, green, and blue sub-pixels, resulting in a more uniform light output and enhanced color balance. Structural features such as tapered sidewalls on the anti-reflection pattern and reverse tapered or vertical profiles on the bank layer further contribute to improved light extraction, minimized non-emissive regions, and effective absorption of incident ambient light.

The bank layer includes a black colorant to block light and enhance contrast. Its optical properties are optimized by selecting materials with a refractive index that promotes light absorption rather than reflection when ambient light enters from the outside. Together, these structural and material choices contribute to a display device that achieves reduced reflection, consistent luminance, and greater environmental efficiency by minimizing power losses without relying on external optical elements.

Accordingly, one or more embodiments of the present disclosure are directed to a display device that substantially obviates one or more of the problems due to the limitations and disadvantages of the related art.

An aspect of the present disclosure is to provide a display device capable of minimizing stains caused by external light reflection with maintaining or improving luminance and with preventing lowering the luminance.

Another aspect of the present disclosure is to provide a display device capable of improving luminous efficiency by extending an emission area.

Another aspect of the present disclosure is to provide a display device capable of emitting light of uniform intensity in each sub-pixel area.

Another aspect of the present disclosure is to provide a display device capable of improving flexibility and applying to a foldable product.

Another aspect of the present disclosure is to provide a display device capable of removing a polarizing member.

Another aspect of the present disclosure is to provide a display device that implements low reflection and low power, thereby being environmentally friendly and pursuing ESG (Environmental, Social and Governance).

Additional features and aspects will be set forth in the description that follows, and in part will be apparent from the description, or can be learned by practice of the disclosed concepts provided herein. Other features and aspects of the disclosed concept can be realized and attained by the structure particularly pointed out in the written description, or derivable therefrom, and the claims hereof as well as the appended drawings.

To achieve these and other aspects of the inventive concepts, as embodied and broadly described, in one aspect, the present disclosure provides a display device that comprises a substrate having an emission area and a non-emission area; a light emitting diode disposed on the substrate correspondingly to the emission area; a bank layer disposed on the substrate correspondingly to the non-emission area; and an anti-reflection pattern disposed between the light emitting diode and the bank layer, and comprising a blue colorant, wherein the light emitting diode comprises a first electrode, a second electrode facing the first electrode and an emissive layer disposed between the first electrode and the second electrode.

In one embodiment, a side surface of the anti-reflection pattern, which is in contact with an outside of the emissive layer, can have a cross-sectional shape inclined downwardly toward the emissive layer.

In another embodiment, a side surface of the bank layer, which is in contact with an outside of the anti-reflection pattern, can have a cross-sectional shape inclined downwardly toward an opposite side of the anti-reflection pattern.

In another embodiment, a side surface of the bank layer, which is in contact with an outside of the anti-reflection pattern, can be disposed perpendicular to a surface of the first electrode.

In another embodiment, the display device can further comprise a column spacer disposed on the bank layer.

As an example, the column spacer can comprise a blue colorant.

In one embodiment, each of the anti-reflection pattern and the bank layer can be disposed to cover a portion of a surface of the first electrode.

In another embodiment, the anti-reflection pattern can be disposed to cover a portion of the first electrode and the bank layer can be disposed an outside of the first electrode.

As an example, the bank layer can have refractive index equal to or more than refractive index of the anti-reflection pattern.

The bank layer comprise a material that blocks light or absorbs light, for example, a black colorant.

In another aspect, the present disclosure is to provide a display device that comprises a substrate having an emission area and a non-emission area; a light emitting diode disposed on the substrate correspondingly to the emission area; a bank layer disposed on the substrate correspondingly to the non-emission area; and a column spacer extending from an upper surface of the bank layer to an area between the light emitting diode and the bank layer, and comprising a blue colorant, wherein the light emitting diode comprises a first electrode, a second electrode facing the first electrode and an emissive layer disposed between the first electrode and the second electrode.

In one embodiment, a side surface of the column spacer, which is in contact with an outside of the emissive layer, can have a cross-sectional shape inclined downwardly toward the emissive layer.

For example, the column spacer can comprise a body component disposed on the bank layer; a connecting component extends toward the light emitting diode from the body component; and an inclined component having a cross-sectional shape inclined downwardly from the connecting component, and the inclined component can be disposed between the bank layer and the emissive layer.

In one embodiment, a side surface of the bank layer, which is in contact with the inclined component of the column spacer, can have a cross-sectional shape inclined downwardly toward an opposite side of the inclined component of the column spacer.

In another embodiment, a side surface of the bank layer, which is contact with the inclined component of the column spacer, can be disposed perpendicular to a surface of the first electrode.

In another embodiment, the inclined component of the column spacer and the bank layer can be disposed to cover a portion of a surface of the first electrode.

In another embodiment, the inclined component can be disposed to cover a portion of a surface of the first electrode and the bank layer can be disposed at an outside of the first electrode.

As an example, the column spacer can have a refractive index equal to or more than a refractive index of the bank layer.

In another embodiment, the display device can further comprise a driving thin film transistor disposed on the substrate and connected to the light emitting diode and comprising an oxide semiconductor; an encapsulation layer disposed on the second electrode; and a color filter layer disposed on the encapsulation layer, and the bank layer can comprise a black colorant.

In one or more embodiments, the anti-reflection pattern including the blue colorant is disposed between the light emitting diode and the bank layer, or the column spacer including the blue colorant is extended between the light emitting diode and the bank layer in the display device.

Since there is no need to apply a separate polarizer to the display surface, the luminance of light emitted from the light emitting diode is not reduced. The clearly recognized external light can be absorbed and/or blocked by the anti-reflection pattern and/or the column spacer. In addition, the external light reflection and stains caused by the external light reflection can be further minimized by disposing the bank layer including the black colorant.

The light emitted from the light emitting diode can be transmitted to the display surface through the anti-reflection pattern and/or the column spacer having the blue colorant. As the emission area is extended, the luminous efficiency of the display device can be improved.

In addition, the light emitted from the light emitting diode in the blue sub-pixel can be transmitted to the display surface through the anti-reflection pattern and/or the column spacer. As the emission area in the blue sub-pixel expands, the luminescence intensity in the blue sub-pixel increases. The intensity of light emitted from each sub-pixel area can be controlled uniformly, and the image quality of the display device can be maximized.

In accordance with the present disclosure, the display device can remove the polarizing member to improve flexibility thereof, and therefore, it is possible to implement a foldable display device in which the display area is folded.

The reliability of the black bank layer can be improved with maintaining sufficient optical density of the black bank layer. In addition, a low-reflection display device can be implemented, and ESG can be implemented by proving the advantage of low power, by including the anti-reflection pattern and/or the column spacer and disposing the bank layer with black-containing material.

It is to be understood that both the foregoing general description and the following detailed description are examples and explanatory, and are intended to provide further explanation of the inventive concepts as claimed.

### BRIEF DESCRIPTION OF THE SEVERAL VIEWS OF THE DRAWINGS

The accompanying drawings, which provide a further understanding of the disclosure, are incorporated in and constitute a part of this application, illustrate embodiments of the disclosure and together with the description serve to explain principles of the disclosure.

FIG. 1 illustrates a schematic circuit diagram of a display device in accordance with one or more embodiments of the present disclosure.

FIG. 2 illustrates a schematic cross-sectional view of the display device in accordance with a first embodiment of the present disclosure.

FIG. 3 is a schematic diagram illustrating components of a light emitting diode, an anti-reflection pattern and a bank layer in the display device in accordance with the first embodiment of the present disclosure.

FIG. 4 is a schematic diagram illustrating that the external light reflection is minimized in the display device in accordance with the first embodiment of the present disclosure.

FIG. 5 is a schematic diagram illustrating the sizes of an emission area and a non-emission area when the anti-reflection pattern is disposed between the light emitting diode and the bank layer in accordance with the first embodiment of the present disclosure.

FIG. 6A is a schematic diagram illustrating an emission area in a blue sub-pixel where the anti-reflection pattern is applied in accordance with the first embodiment of the present disclosure.

FIG. 6B is a schematic diagram illustrating an emission area in a red sub-pixel and/or a green sub-pixel where the anti-reflection pattern is applied in accordance with the first embodiment of the present disclosure.

FIGS. 7 to 9 are schematic cross-sectional view illustrating arrangements of the light emitting diode, the anti-reflection pattern and the bank layer in the display device in accordance with other embodiments of the present disclosure.

FIGS. 10 to 12 are simulation results illustrating a reflectance of external light by modification of an internal structure of the bank layer.

FIG. 13 illustrates a schematic cross-sectional view of the display device in accordance with a second embodiment of the present disclosure.

FIG. 14 is a schematic diagram illustrating components of a light emitting diode, a bank layer and a column spacer in the display device in accordance with the second embodiment of the present disclosure.

FIG. 15 is a schematic diagram illustrating that the external light reflection is minimized in the display device in accordance with the second embodiment of the present disclosure.

FIGS. 16 to 18 are schematic cross-sectional view illustrating arrangements of the light emitting diode, the anti-reflection pattern and the bank layer in the display device in accordance with other embodiments of the present disclosure.

FIG. 19 illustrates a schematic exploded perspective view of a display device in accordance with a third embodiment of the present disclosure.

FIG. 20 illustrates a schematic cross-sectional view of the display device in accordance with the third embodiment of the present disclosure.

### DETAILED DESCRIPTION

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same components throughout this disclosure unless otherwise specified. Further, in the following description of the present disclosure, where a detailed description of a known related art can unnecessarily obscure the gist of the present disclosure, the detailed description thereof can be omitted herein or can be briefly discussed.

Where terms such as “including,” “having,” “comprising,” and the like are used in this disclosure, other parts can be added unless a more limiting term like “only” is used herein. Further, where a component is expressed as being singular, being plural is included, and vice versa, unless otherwise specified.

In analyzing a component, an error range should be interpreted as being included even where there is no explicit description.

In describing a positional relationship, for example, where a positional relationship of two parts/layers is described as being “over,” “on,” “above,” “below,” “under,” “next to,” or the like, one or more other parts/layers can be provided between the two parts/layers, unless a more limiting term like “immediately” or “directly” is used therewith.

When a component or layer is referred to as being “on” another component or layer, it includes both instances where the component is directly on the other component or layer, or where there is another layer or component intervening therebetween.

In describing a temporal relationship, for example, where a temporal predecessor relationship is described as being “after,” “subsequent,” “next to,” “prior to,” or the like, unless a more limiting term like “immediately” or “directly” is used, cases that are not continuous or sequential can also be included. Further, the term “can” fully encompasses all the meanings and coverages of the term “may” and vice versa.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

Although the terms first, second, and the like can be used to describe various components, these components are not substantially limited by these terms. These terms are used only to refer to one component separately from another component, and may not define any particular order or sequence. Therefore, a first component described below can substantially be a second component, and vice versa, within the technical spirit of the present disclosure.

Features of various embodiments of the present disclosure can be partially or entirely united or combined with each other, technically various interlocking and driving are possible, and each of the embodiments can be independently implemented with respect to each other or implemented together in a co-dependent relationship.

All the components of each display device according to all embodiments of the present disclosure are operatively coupled and configured.

Reference will now be made in detail to aspects of the disclosure, examples of which are illustrated in the accompanying drawings. Wherever possible, the same reference numbers will be used throughout the drawings to refer to the same or like parts.

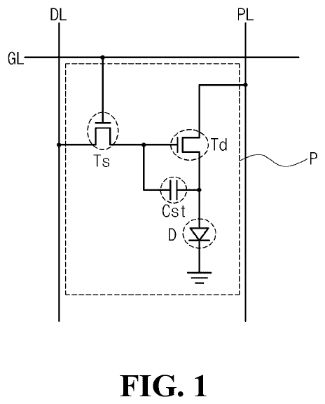

FIG. 1 illustrates a schematic circuit diagram of a light emitting display device in accordance with one or more embodiments of the present disclosure.

Referring to FIG. 1, the display device in accordance with the present disclosure includes a gate line GL, a data line DL and a power line PL crossing each other to define a pixel region P. A switching thin film transistor Ts, a driving thin film transistor Td, a storage capacitor Cst and a light-emitting diode D can be disposed in the pixel region P. A pixel region P can comprise a first sub-pixel region, a second sub-pixel region, a third sub-pixel region, and optionally, a fourth sub-pixel region. As an example, the first sub-pixel region can be a red (R) sub-pixel region, the second sub-pixel region can be a green (G) sub-pixel region, the third sub-pixel region can be a blue (B) sub-pixel region, and the fourth sub-pixel region can be a white (W) sub-pixel region, but is not limited thereto.

The switching thin film transistor Ts is connected to the gate line GL and the data line DL. The driving thin film transistor Td and the storage capacitor Cst are connected between the switching thin film transistor Ts and the power line PL, and the light emitting diode D is connected to the driving thin film transistor Td.

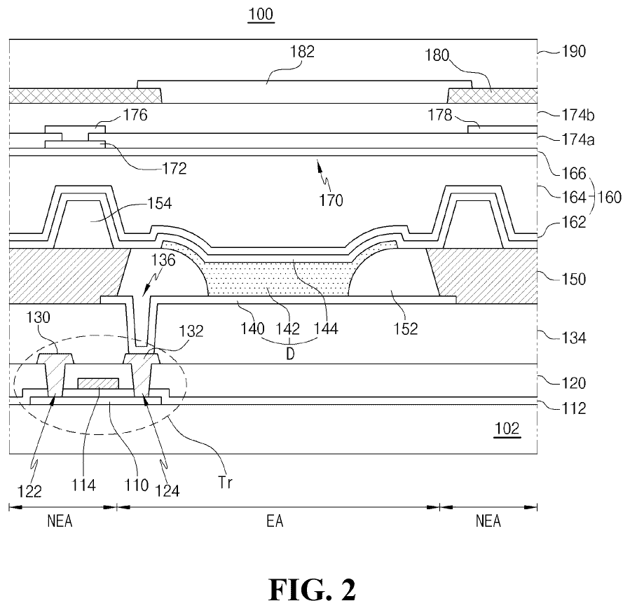

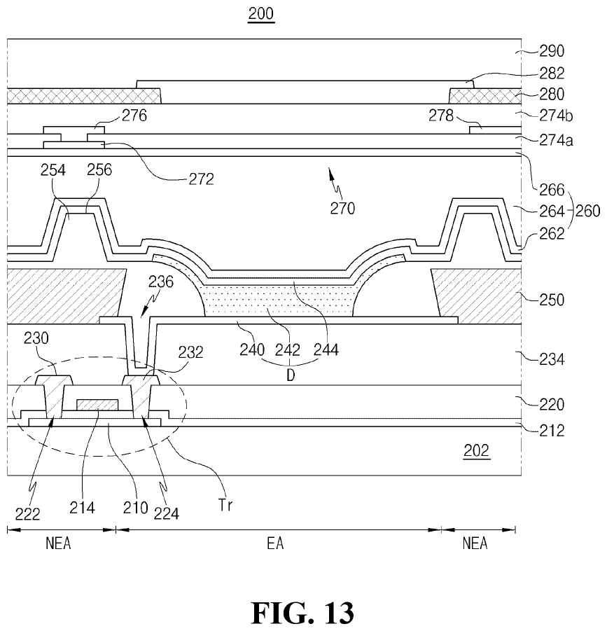

In the display device, when the switching thin film transistor Ts is turned on by a gate signal applied to the gate line GL, a data signal applied to the data line DL is applied to a gate electrode 114 or 214 (FIG. 2 or FIG. 13) of the driving thin film transistor Td and one electrode of the storage capacitor Cst through the switching thin film transistor Ts.

The driving thin film transistor Td is turned on by the data signal applied to the gate electrode 114 or 214 so that a current proportional to the data signal is supplied from the power line PL to the light-emitting diode D through the driving thin film transistor Td. And then, the light-emitting diode D emits light having a luminance proportional to the current flowing through the driving thin film transistor Td. In this case, the storage capacitor Cst is charged with a voltage proportional to the data signal so that the voltage of the gate electrode 114 or 214 in the driving thin film transistor Td is kept constant during one frame. Therefore, the display device can display a desired image.

In one embodiment, the switching thin film transistor Ts and/or the driving thin film transistor Td can comprise, but is not limited to, a polycrystalline semiconductor material such as low temperature polycrystalline silicon (LTPS) and/or an oxide semiconductor. For example, the switching thin film transistor Ts and/or the driving thin film transistor Td can be a transistor of a low temperature polycrystalline and oxide (LPTO) type including the LTPS and the oxide semiconductor, but is not limited thereto. In another embodiment, the driving thin film transistor Td can be a transistor of a Complementary Metal Oxide Semiconductor (CMOS) type combining a p-Channel Metal Oxide Semiconductor (PMOS) and an n-Channel Metal Oxide Semiconductor (NMOS), but is not limited thereto.

### First Embodiment

FIG. 2 illustrates a schematic cross-sectional view of the display device in accordance with a first embodiment of the present disclosure.

Referring to FIG. 2, a display device 100 includes a substrate 102, and a light emitting diode D and a bank layer 150 disposed on the substrate 102, and optionally or additionally, a thin film transistor Tr disposed on the substrate 102 and a color filter layer 182 disposed on the light emitting diode D.

The pixel region P (FIG. 1) including the red sub-pixel region, the green sub-pixel region and the blue sub-pixel region can be defined in the substrate 102. The pixel region P can further include the white sub-pixel region. In addition, the substrate 102 can comprise an emission area EA and a non-emission area NEA disposed adjacently to the emission area EA or surrounds the emission area EA.

The substrate 102 can comprise, but is not limited to, a glass substrate, a flexible substrate or a polymer plastics substrate. For example, the substrate 102 can be configured to have at least one of a polyimide (PI) substrate, a polyether sulfone (PES) substrate, a polyethylene naphthalate (PEN) substrate, a polyethylene terephthalate (PET) substrate and a polycarbonate (PC) substrate.

The thin film transistor Tr is disposed on the substrate 102. In FIG. 2, the thin film transistor Tr is disposed directly on the substrate 102. Alternatively, a first buffer layer can be disposed on the substrate 102 and the thin film transistor Tr can be disposed on the first buffer layer. For example, the first buffer layer can comprise, but is not limited to, silicon oxide (SiOₓ) and/or silicon nitride (SiNₓ) (wherein 0<x≤2).

The thin film transistor Tr can comprise a semiconductor layer 110, a gate electrode 114, a source electrode 130 and a drain electrode 132. The thin film transistor Tr can be the driving thin film transistor Td (FIG. 1).

The semiconductor layer 110 is disposed on the substrate 102. In one embodiment, the semiconductor layer 110 can comprise an oxide semiconductor material. For example, the oxide semiconductor can be selected from, but is not limited to, Indium Gallium Zinc oxide (IGZO), Indium Zinc Tin oxide (IZTO), Zinc Gallium Tin oxide (ZGTO), Zinc Tin oxide (ZTO), Zinc Gallium oxide (ZGO), Zinc oxide (ZnO) and combinations thereof. When the semiconductor layer 110 comprises the oxide semiconductor material, a light shielding pattern can be disposed under the semiconductor layer 110. The light shielding pattern can prevent the light from being incident to the semiconductor layer 110, and thereby the semiconductor layer 110 from being deteriorated by the light. In another embodiment, the semiconductor layer 110 can comprise a polycrystalline semiconductor. In this case, impurity can be doped to both sides of the semiconductor layer 110.

A gate insulating layer 112 can be disposed on the semiconductor layer 110 with covering the entire substrate 102. For example, the gate insulating layer 112 can comprise, but is not limited to, an inorganic insulating material such as silicon oxide (SiOₓ) and/or silicon nitride (SiNₓ) (wherein 0<x≤2).

The gate electrode 114 including a conductive material such as metal is disposed on the gate insulating layer 112 corresponding to a center of the semiconductor layer 110. For example, the gate electrode 114 can comprise, but is not limited to, a metal component such as copper (Cu), molybdenum (Mo), titanium (Ti), aluminum (Al), gold (Au), and silver (Ag). The gate electrode 114 can have a mono-layer structure or a multi-layer structure. In FIG. 2, while the gate insulating layer 112 can be disposed on the entire substrate 102, but the gate insulating layer 112 can be patterned as the gate electrode 114.

An interlayer insulating layer 120 is disposed on the gate electrode 114 with covering the entire substrate 102. For example, the interlayer insulating layer 120 can comprise, but is not limited to, an inorganic insulating material such as silicon oxide (SiOₓ) and silicon nitride (SiNₓ) (wherein 0<x≤2) or an organic insulating material such as benzocyclobutene and/or photo-acryl.

The interlayer insulating layer 120 has first and second semiconductor contact holes 122 and 124 that expose or do not cover the both sides of the semiconductor layer 110. The first and second semiconductor contact holes 122 and 124 are located spaced apart from the gate electrode 114 at both sides of the gate electrode 114. In FIG. 2, the first and second semiconductor contact holes 122 and 124 are disposed in the interlayer insulating layer 120 and the gate insulating layer 112. In another embodiment, when the gate insulating layer 112 is patterned as the gate electrode 114, the first and second semiconductor contact holes 122 and 124 can be formed in only the interlayer insulating layer 120.

The source electrode 130 and the drain electrode 132 comprising a conductive material such as metal component are disposed on the interlayer insulating layer 120. The source electrode 130 and the drain electrode 132 are spaced apart from each other with centering the gate electrode 114, and contact to both sides of the semiconductor layer 110 through the first and second semiconductor contact holes 122 and 124, respectively. In one embodiment, the source electrode 130 can be an input electrode connecting to a high potential driving power and the drain electrode 132 can be an output electrode connecting to a switch circuit, but is not limited thereto. The amount of current flowing to the light emitting diode D can be controlled by voltage differences between the gate electrode 114 and the source electrode 130.

For example, the source electrode 130 and the drain electrode 132 can comprise, but is not limited to, the metal component such as copper (Cu), molybdenum (Mo), titanium (Ti), aluminum (Al), gold (Au) and/or silver (Ag). The source electrode 130 and the drain electrode 132 can have a mono-layer structure or a multi-layer structure.

In FIG. 2, the thin film transistor Tr has a coplanar structure where the gate electrode 114, the source electrode 130 and the drain electrode 132 are disposed on the semiconductor layer 110. In another embodiment, the thin film transistor can have an inverted staggered structure where the gate electrode is disposed under the semiconductor layer and the source electrode and the drain electrode are disposed on the semiconductor layer. In this case, the semiconductor layer can comprise amorphous silicon.

The thin film transistor Tr can be the driving thin film transistor Td (FIG. 1). For example, the driving thin film transistor Td can comprise the oxide semiconductor, but is not limited thereto.

A planarization layer 134 is disposed on the source electrode 130 and the drain electrode 132 with covering the entire substrate 102. The planarization layer 134 can be disposed to cover the thin film transistor Tr.

The planarization layer 134 has a flat surface and has a drain contact hole 136 that exposes or do not cover the drain electrode 132. For example, the planarization layer 134 can comprise, but is not limited to, an inorganic insulating material such as silicon oxide (SiOₓ) and silicon nitride (SiNₓ) (wherein 0<x≤2) or an organic insulating material such as benzocyclobutene and/or photo-acryl.

The light emitting diode D is disposed on the planarization layer 134 correspondingly to the emission area EA. The light emitting diode D comprises a first electrode 140 disposed on the planarization layer 134 and connected to the drain electrode 132, and an emissive layer 142 and a second electrode 144 that are laminated sequentially on the first electrode 140. As an example, the light emitting diode D can be positioned in each of the red sub-pixel region, the green sub-pixel region and the blue sub-pixel region and can emit red light, green light and blue light, respectively.

The first electrode 140 can be disposed separately in each sub-pixel region. The first electrode 140 can be an anode and can comprise a conductive material with relatively high work function value, for example, a transparent conductive oxide (TCO). For example, the first electrode 142 can comprise, but is not limited to, Indium Tin oxide (ITO), Indium Zinc oxide (IZO), Indium Tin Zinc oxide (ITZO), Tin oxide (SnO), Zinc oxide (ZnO), Indium Copper oxide (ICO) and/or Aluminum: Zinc oxide (AZO).

In one embodiment, the first electrode 14 can have a mono-layer structure of the transparent conductive oxide. In another embodiment, the first electrode can have a bi-layer structure or a triple-layer structure with further comprising a reflective layer. In this case, the first electrode 140 can be a reflective electrode.

In one embodiment, the reflective layer can comprise, but is not limited to, silver (Ag), an alloy including silver (Ag) and at least one of palladium (Pd), copper (Cu), indium (In) and neodymium (Nd), and/or an aluminum-palladium-copper (APC) alloy. For example, the first electrode 140 can have a bi-layer structure of Ag/ITO or APC/ITO or a triple-layer structure of ITO/APC/ITO.

The bank layer 150 is disposed on the planarization layer 134 with covering the periphery area of the first electrode 140 correspondingly to the non-emission area NEA. The bank layer 150 exposes or do not cover the center of the first electrode 140 corresponding to the sub-pixel region. For example, the bank layer 150 can comprise a light-blocking or light-absorbing material. Alternatively, a color filter layer including red, green and/or blue colorants can be laminated on the bank layer 150.

An anti-reflection pattern 152 including a blue colorant is disposed between the light emitting diode D and the bank layer 150 in accordance with the first embodiment. In this case, the emissive layer 142 of the light emitting diode D is disposed to be spaced apart from the bank layer 150. The stains caused by the reflection of external or ambient light can be minimized and the emission area EA can be expanded by applying the anti-reflection pattern 152 between the light emitting diode D and the bank layer 150.

A column spacer 154 is disposed on the bank layer 150. The column spacer 154 can be disposed to surround the emission area EA where the light emitting diode D is disposed in each sub-pixel region. The column spacer 154 can be patterned from a composition including a colorant and absorb a reflective light and the external light.

For example, the column spacer can have a cross-sectional shape where the width gradually increases toward the bank layer (a trapezoidal cross-sectional shape or a tapered cross-sectional shape), or a cross-sectional shape where the width gradually decreases toward the bank layer 150 (an inverted-trapezoidal cross-sectional shape or an inverted-tapered cross-sectional shape), but is not limited thereto.

The emissive layer 142 is disposed on the first electrode 140. As an example, the emissive layer 142 can have a mono-layer structure of an emitting material layer (EML). The EML can comprise an organic luminescent material or an inorganic luminescent material. In other words, the display device 100 can be an organic light emitting display device or an inorganic light emitting display device.

In the organic light emitting display device, the EML can comprise a host and a dopant as an emitter. The EML can comprise a red host and a red dopant in the red sub-pixel. The EML can comprise a green host and a green dopant in the green sub-pixel. The EML can comprise a blue host and a blue dopant in the blue sub-pixel. In the inorganic light emitting display device, the EML can comprise quantum dots as the inorganic luminescent material.

In another embodiment, the emissive layer 142 can have a multi-layer structure. As an example, the emissive layer 142 can further comprise at least one of a hole injection layer (HIL), a hole transport layer (HTL), an electron blocking layer (EBL), a hole blocking layer (HBL), an electron transport layer (ETL) and an electron injection layer (EIL) in addition to the EML.

In one embodiment, the light emitting diode D can emit white light in each of the red sub-pixel, the green sub-pixel and the blue sub-pixel. For example, the emissive layer 142 of the light emitting diode D can have a double-stack structure including a first emitting unit including a first emitting material layer, a second emitting unit including a second emitting material layer and a charge generation layer (CGL) disposed between the first emitting unit and the second emitting unit. IN another embodiment, the emissive layer 142 of the light emitting diode D can have a triple-stack structure further including a third emitting unit including a third emitting material layer and another charge generation layer between the second emitting unit and the third emitting unit.

The second electrode 144 is disposed on the substrate 102 onto which the emissive layer 142 is disposed. The second electrode 144 can be disposed on the entire display area and can comprise a conductive material with relatively low work function value to act as a cathode. For example, the second electrode 144 can comprise, but is not limited to, aluminum (Al), magnesium (Mg), calcium (Ca), silver (Ag), and alloys thereof such as magnesium silver alloy. The second electrode 144 can have a thin thickness to have a light-transmissive (semi-transmissive) property.

An encapsulation layer (encapsulation film) 160 is disposed on the second electrode 144 in order to prevent external oxygen and/or moisture from infiltrating to the light emitting diode D. In one embodiment, the encapsulation layer 160 can have, but is not limited to, a lamination structure of a first inorganic insulating layer 162, an organic insulating layer 164 and a second inorganic insulating layer 166.

Each of the first inorganic insulating layer 162 and the second inorganic insulating layer 166 can comprise, but is not limited to, an inorganic insulating material such as silicon oxide (SiOₓ) and silicon nitride (SiNₓ) (wherein 0<x≤2). The organic insulating layer 164 can comprise, but is not limited to, an organic insulating material such as an epoxy resin, photo-acryl (or photosensitive acrylic polymer). The organic insulating layer 164 is disposed between the first inorganic insulating layer 162 and the second inorganic insulating layer 166. The organic insulating layer 164 makes the lower step to flatten and provides a flat surface.

A touch sensor 170 can be disposed on the encapsulation layer 160 to provide a sensing function. As an example, the touch sensor 170 can comprise a connection (or bridge) electrode 172 disposed on the encapsulation layer 160, a first touch insulating layer 174a having first and second contact holes exposing both sides of the connection electrode 172, a first touch electrode 176 and a second touch electrode 172 disposed on the first touch insulating layer 174a, and a second touch insulating layer 174b disposed on the first and second touch electrodes 176 and 178. Adjacent first touch electrodes 176 can be electrically connected to each other through the first and second contact holes.

For example, the first touch insulating layer 174a can comprise, but is not limited to, an inorganic insulating material such as silicon oxide (SiOₓ) and/or silicon nitride (SiNₓ) (wherein 0<x≤2). Alternatively or additionally, a second buffer layer can be disposed between the second inorganic insulating layer 166 of the encapsulation 1ayer 160 and the first touch insulating layer 174a. The second buffer layer can comprise, but is not limited to, an inorganic insulating material such as silicon oxide (SiOₓ) and/or silicon nitride (SiNₓ) (wherein 0<x≤2). For example, the second touch insulating layer 174b can comprise, but is not limited to, an inorganic insulating material such as silicon oxide (SiOₓ) and/or silicon nitride (SiNₓ) (wherein 0<x≤2), or an organic insulating material such as benzocyclobutene or photo-acryl.

Each of the plurality of touch electrodes 176 and 178 can be disposed correspondingly to the boundary of sub-pixel region. As an example, each of the plurality of touch electrodes 176 and 178 can be disposed correspondingly to the bank layer 150 and/or a black matrix 180, but the alignment structure of the touch electrodes 176 and 178 is not limited thereto. For example, the touch electrode 176, 178 can comprise, but is not limited to, a transparent metal oxide such as ITO, IZO, ITZO, SnO, ZnO, ICO and/or AZO.

A black matrix 180 and a color filter layer 182 are disposed on the second touch insulating layer 174b. In another embodiment, the touch sensor 170 including the connection electrode 172, the first touch insulating layer 174a, a first touch electrode 176, a second touch electrode 178 and the second touch insulating layer 174b can be omitted, and the black matrix 180 and the color filter layer 182 can be disposed on the encapsulation layer 160.

The black matrix 180 is disposed in a periphery of the sub-pixel region correspondingly to the non-emission area NEA and has an opening corresponding to the light emitting diode D. For example, the black matrix 180 can comprise a light-shielding material or a light-absorbing material such as a black resin and/or carbon black. Alternatively or additionally, a color filter layer including a red (R), green (G) and/or blue (B) colorants can be laminated on the black matrix 180.

The color filter layer 182 is disposed correspondingly to the openings of the black matrix 180. In other words, the color filter layer 182 is disposed on the encapsulation layer 160 or the touch sensor 170 correspondingly to the emission area EA. When the sub-pixel region includes the red sub-pixel, the green sub-pixel and the blue sub-pixel, the color filter layer 182 can comprise a red color filter pattern corresponding to the red sub-pixel, a green color filter pattern corresponding to the green sub-pixel and a blue color filter pattern corresponding to the blue sub-pixel.

The red color filter pattern can comprise at least one of a red dye and a red pigment. The green color filter pattern can comprise at least one of a green dye and a green pigment. The blue color filter pattern can comprise at least one of a blue dye and a blue pigment.

In another embodiment, a passivation layer is disposed on the second touch insulating layer 174b with covering the entire substrate 102, and the black matrix 180 and the color filter layer 182 can be disposed on the passivation layer. The passivation layer can comprise, but is not limited to, an inorganic insulating material such as silicon oxide (SiOₓ) and/or silicon nitride (SiNₓ) (wherein 0<x≤2).

A first insulating layer 190 can be disposed on the color filter layer 182 with covering the entire substrate 102. For example, the first insulating layer 190 can comprise, but is not limited to, an organic insulating material such as an epoxy resin and/or photo-acryl. Alternatively or additionally, a second insulating layer can be disposed on the first insulating layer 190.

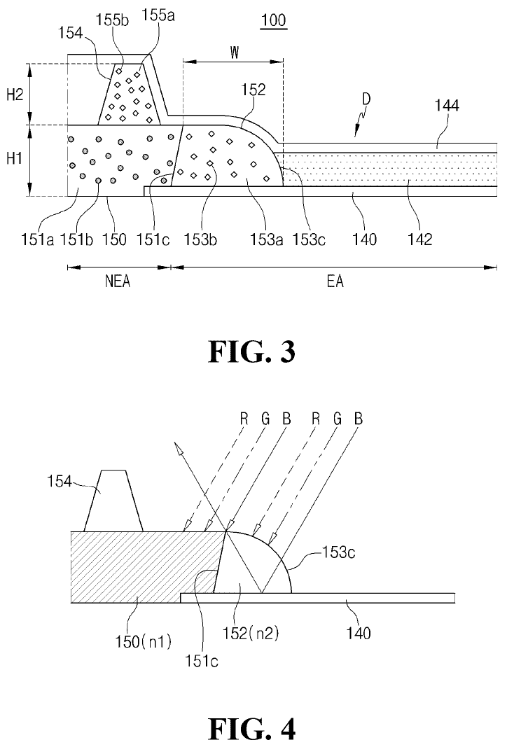

In an embodiment, a side surface 151c (FIG. 3) of the bank layer 150 adjacent to the emission area EA covering the first electrode 140 can be further extended toward the emission area EA than a side surface of the black matrix 180 adjacent to the color filter layer 182 so as to have a “Pull Back” structure, but is not limited thereto.

The structures and arrangements of the light emitting diode, the anti-reflection pattern, the bank layer and the column spacer in accordance with the present disclosure will be described in more detail. FIG. 3 is a schematic diagram illustrating components of a light emitting diode, an anti-reflection pattern and a bank layer in the display device in accordance with the first embodiment of the present disclosure.

Referring to FIG. 3, the bank layer 150 is disposed to be spaced apart from a side of the emissive layer 142 constituting the light emitting diode D. The anti-reflection pattern 152 is disposed between the emissive layer 142 and the bank layer 150. As an example, the bank layer 150 and the anti-reflection pattern 152 can be disposed to cover a portion of the first electrode 140, for example, the periphery area of the first electrode 140.

The bank layer 150 can comprise a first photosensitive binder resin 151a and a light-blocking or light-absorbing material (hereinafter, light-blocking material) 151b. The anti-reflection pattern 152 between the light emitting diode D and the bank layer 150 can comprise a second photosensitive binder resin 153a and a blue colorant 153b. In addition, the column spacer 154 can comprise a third photosensitive binder resin 155a and a colorant 155b.

For example, each of the first photosensitive binder resin 151a, the second photosensitive binder resin 153a and the third photosensitive binder resin 155a can independently comprise, but is not limited to, an acryl-containing binder resin, a methacyl-containing binder resin, an acrylamide-containing binder resin, an imide-containing binder resin, an epoxy-containing binder resin, a cardo-containing binder resin, a fluorene-containing binder resin, a siloxane-containing binder resin, copolymers thereof or combinations thereof.

The light-blocking material 151b in the bank layer 150 can comprise a black colorant capable of absorbing light and/or a material capable of blocking light such as a black dye and/or a black pigment. For example, the light-blocking material 151b can comprise, but is not limited to, a carbon black, carbon nanotube (CNT), graphene, an organic black, a black pigment, perylene-containing material, an azo-containing material, a nano-based carbon material, a hybrid type of red/green/blue pigment or dye, or a multi-layered thin film material. In another embodiment, the light-blocking material 151b can comprise an organic material that is oxidized and converted to black in the post-baking process.

The blue colorant 153b in the anti-reflection pattern 152 can comprise, but is not limited to, a blue dye and/or a blue pigment. For example, the blue colorant 153b can comprise a phthalocyanine-containing blue dye, an indanthrone-containing blue dye, a triarylmethane-containing blue dye, a copper phthalocyanine-containing blue dye or combinations thereof. The anti-reflection pattern 152 including the blue colorant 153b is disposed between the light emitting diode D and the bank layer 150, for example, between the emissive layer 142 and the bank layer 150. Accordingly, it is possible to minimize the reflection of external light and expand the emission area EA in the display device 100.

The colorant 155b in the column spacer 154 can be a light-blocking material. For example, the colorant 155b in the column spacer 154 can be the same as the light-blocking material 151b in the bank layer 150. In another embodiment, the colorant 155b in the column spacer 154 can comprise a blue colorant. For example, the colorant 155b in the column spacer 154 can be the same as the blue colorant 153b in the anti-reflection pattern 152.

In one embodiment, a height H1 of the bank layer 150 and the anti-reflection pattern 152 and a height H2 of the column spacer 154 can be, but is not limited to, about 1 μm to about 3 μm.In another embodiment, a width W of the anti-reflection pattern 152 disposed between the light emitting diode D and the bank layer 150 can be, but is not limited to, about 0.5 μm to about 3 μm, for example, about 0.5 μm to about 2μm. When the width W of the anti-reflection pattern 152 is less than 0.5 μm, the emission area EA cannot be sufficiently expanded. When the width W of the anti-reflection pattern 152 is more than 3 μm, it is difficult to implement the Pull-Back structure.

The bank layer 150, the anti-reflection pattern 152 and the column spacer 154 can be disposed or arranged on the planarization layer 134, the first electrode 140 and the bank layer 150, respectively, by coating a photosensitive composition including the photosensitive binder resin 151a, 153a or 155a; a solvent; the light-blocking material 151b, the blue colorant 153b or the colorant 155b; and an additive such as dispersant on the planarization layer 134, the first electrode 140 and the bank layer 150, respectively, and then performing a photoresist (PR) process using a mask. For example, each of the anti-reflection pattern 152 and the column spacer 154 can be disposed on the first electrode 140 and the bank layer 150, respectively, by performing a negative photoresist process using a full-tone mask, but is not limited thereto.

In one exemplary embodiment, a side surface 153c of the anti-reflection pattern 152, which is in contact with or facing a side of the emissive layer 142 of the light emitting diode D, can have a cross-sectional shape inclined downwardly toward the light emitting diode D, for example, the emissive layer 142. For example, the side surface 153c of the anti-reflection pattern 152 can have a cross-sectional shape of which the width gradually increases toward the first electrode or a tapered cross-sectional shape, but is not limited thereto.

The side surface 153c of the anti-reflection pattern 152 may be curved with a predetermined curvature, or may extend downwardly without the curvature. For example, the side surface 153c of the anti-reflection pattern 152 can be disposed with an angle of about 30° to about 60° with respect to the first electrode 140, but is not limited thereto. As the side surface 153c of the anti-reflection pattern 152 has the tapered cross-sectional shape, the occurrence of a dead point in the light emitting diode can be minimized, and disconnection or lifting in the light emitting diode D can be prevented.

In another embodiment, a side surface 151c of the bank layer 150, which is in contact with the other side surface of the anti-reflection pattern 152, can have a cross-sectional shape inclined downwardly toward an opposite side of the anti-reflection pattern 152. In other words, with respect to the bank layer 150, the side surface 151c of the bank layer 150 can have a cross-sectional shape of which the width gradually decreases toward the first electrode 140, or a reverse tapered cross-sectional shape. For example, the side surface 151c of the bank layer 150 can be disposed with an angle greater than 90° and equal to or less than 150° with respect to the first electrode 140, but is not limited thereto.

When the side surface 151c of the bank layer 150 has the same tapered cross-sectional shape as the side surface 153c of the anti-reflection pattern 152, the surface area of the upper portion of the bank layer 150 is reduced, and therefore, absorption and blocking of external light are greatly reduced in the upper portion of the bank layer 150. Accordingly, there is a limitation in efficiently preventing reflection of external light and stains caused by reflections of external light.

On the contrary, when the side surface 151c of the bank layer 150 has the reverse tapered cross-sectional shape, the upper portion of the bank layer 150 where the external light incidents has a relatively great surface area compared to the lower portion of the bank layer 150. Accordingly, as the amount of external light absorbed or blocked in the upper portion of the bank layer 150 increases, it is possible to minimize the reflection of external light and stains such as rainbow mura caused by the reflection of external light.

FIG. 4 is a schematic diagram illustrating that the external light reflection is minimized in the display device in accordance with the first embodiment of the present disclosure.

Referring to FIG. 4, all the red light R, the green light G and the blue light B which are the light in the visible region among the external light are absorbed and blocked in the bank layer 150 including the light-blocking material 151b (FIG. 3). Accordingly, reflection of external light can be minimized and stains caused by the reflection of external light can be prevented.

In addition, the red light R and the green light G among the external light are absorbed and blocked by the anti-reflection pattern 152 including the blue colorant 153b (FIG. 3). On the contrary, the blue light B incident on the anti-reflection pattern 152 transmits or passes through the anti-reflection pattern 152, and some of the blue light B is reflected from the first electrode 140.

Among the electromagnetic waves in the visible wavelength band, the green light around the wavelength band of about 555 nm is most brightly visible to human eyes. In addition, compared to the red light around the wavelength band of about 600 nm, the blue light around the wavelength band of about 500 nm is hardly visible to human eye.

The red light R and the green light G, which are relatively clearly recognized by the human eye, among the external light in the visible wavelength band, cannot pass through the anti-reflection pattern 152 including the blue colorant 151b (FIG. 3). That is, the red light R and the green light G among the external light incident on the anti-reflection pattern 152 are blocked by the anti-reflection pattern 152 and are not reflected to the outside. In other words, the red light R and the green light G, which are relatively easily recognized by the human eye, among the external light are absorbed and blocked by the anti-reflection pattern 152. Reflection of external light corresponding to the wavelength bands of the red light R and the green light G is not recognized. Only the blue light B, which is hardly visible to human eyes, is reflected by the anti-reflection pattern 152. Accordingly, reflection of external light can be efficiently prevented by applying the anti-reflection pattern 152, and stains caused by reflection of external light can be minimized.

In one embodiment, the bank layer 150 can have a first refractive index n1 equal to or more than a second refractive index n2 of the anti-reflection pattern 152. When the external light passing through the anti-reflection pattern 152, which is a relatively less dense medium, is incident on the bank layer 150, which is a relatively dense medium, it is refracted to the bank layer 150 without total reflection. And then, the external light incident on the bank layer 150 can be efficiently absorbed and blocked by the bank layer 150 including the light-blocking material 151b (FIG. 3). For example, the first refractive index n1 of the bank layer 150 can be about 1.6 to about 1.9, and the second refractive index n2 of the anti-reflection pattern 152 can be about 1.5 to about 1.8, but is not limited thereto.

An ambient light diffraction mura due to the step difference caused by the thin film transistor Tr may occur. In addition, as the diffraction of the reflected external light is further enhanced by the color filter layer 182, a rainbow mura may occur due to interference between adjacent sub-pixel regions. However, the anti-reflection pattern 152 including the blue colorant 153b is disposed between the light emitting diode D and the bank layer 150 in accordance with the first embodiment of the present disclosure, thereby effectively blocking the external light that is clearly visible to human eyes, and thereby reducing external light reflection. Since the polarizer is not used, it is possible to prevent deterioration in image quality due to external light reflection with minimizing a decrease in emission luminance due to the polarizer.

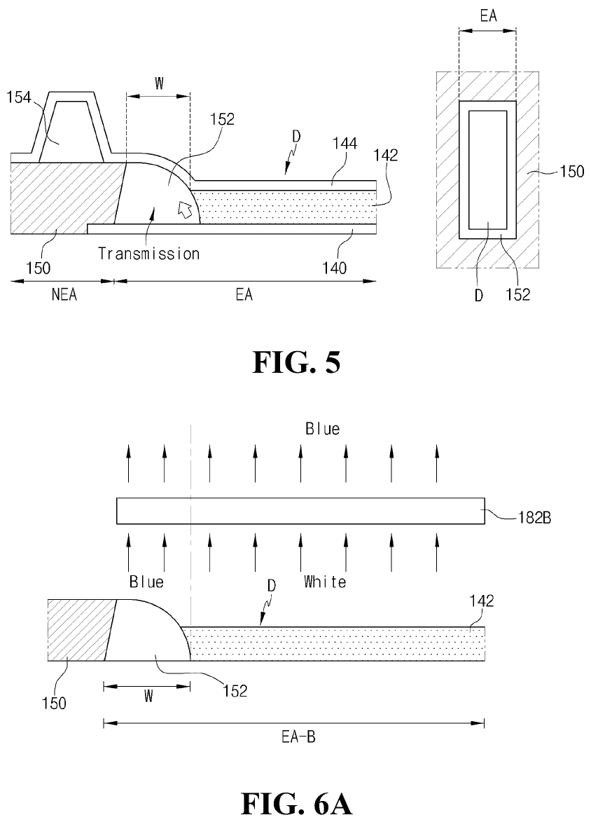

Subsequently, an expansion of the emission area by introducing the anti-reflection pattern will be described. FIG. 5 is a schematic diagram illustrating the sizes of an emission area and a non-emission area when the anti-reflection pattern is disposed between the light emitting diode and the bank layer in accordance with the first embodiment of the present disclosure.

When the anti-reflection pattern 152 including the blue colorant 153b (FIG. 3) is disposed between the light emitting diode D and the bank layer 150 in accordance with the first embodiment, the blue light among the light emitted from the emissive layer 142 can pass through the anti-reflection pattern 152 and transmitted to the display surface. In this case, the emission area EA can be expanded by the width W of the anti-reflection pattern 152 in the display device 100 in accordance with the first embodiment. As the emission area EA is expanded, the intensity of light transmitted to the display surface in each sub-pixel region, and the luminous efficiency of the display device 100 can be improved.

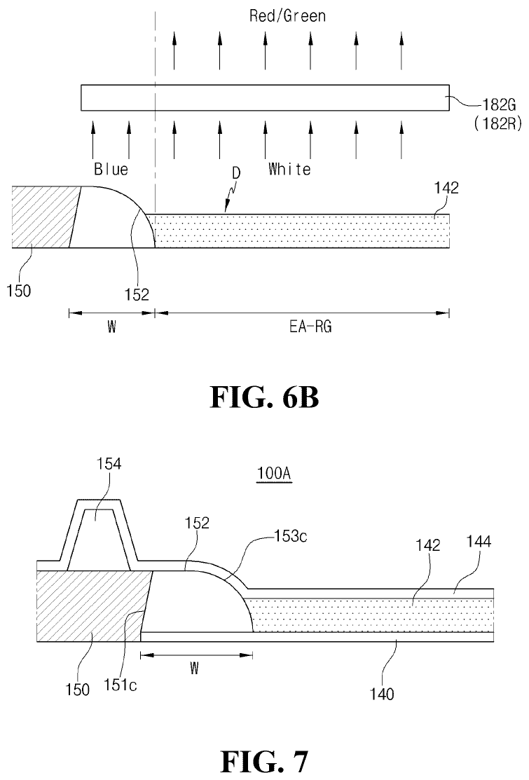

FIG. 6A is a schematic diagram illustrating an emission area in a blue sub-pixel where the anti-reflection pattern is applied in accordance with the first embodiment of the present disclosure. FIG. 6B is a schematic diagram illustrating an emission area in a red sub-pixel and/or a green sub-pixel where the anti-reflection pattern is applied in accordance with the first embodiment of the present disclosure.

In FIGS. 6A and 6B, the display device in which the white light is emitted from the light emitting diode D is described. Referring to FIG. 6A, the white light W emitted from the upper surface of the light emitting diode D in the blue sub-pixel is transmitted to the upper surface. The blue light B among the white light emitted to the side surface of the light emitting diode D can pass through the anti-reflection pattern 152 including the blue colorant 153b (FIG. 3).

Both the white light emitted from the upper surface of the light emitting diode D, and the blue light B emitted from the side surface of the light emitting diode D and passing through the anti-reflection pattern 152 can pass through a blue color filter pattern 182B. Accordingly, in the blue sub-pixel, the blue light B can be transmitted to the display surface in an area emitted to the upper surface of the light emitting diode D and an area transmitted through the anti-reflection pattern 152 having the width W. In the blue sub-pixel, the emission area EA-B is expanded by adding the width W of the anti-reflection pattern 152 in addition to the width of the emissive layer 142.

Referring to FIG. 6B, the white light emitted from the upper surface of the light emitting diode D in the red sub-pixel and the green sub-pixel is transmitted to the upper surface. Only the blue light B among the white light emitted to the side surface of the light emitting diode D can pass through the anti-reflection pattern 152 including the blue colorant 153b (FIG. 3).

In the red sub-pixel and the green sub-pixel, the white light emitted from the upper surface of the light emitting diode D can pass through a red color filter pattern 182R or a green color filter pattern 182G and then the red light R or the green light G can be transmitted to the display surface. However, in the red sub-pixel and the green sub-pixel, the blue light B emitted from the side surface of the light emitting diode D and passing through the anti-reflection pattern 152 cannot pass through the red color filter pattern 182R and/or the green color filter pattern 182G. In the red sub-pixel and the green sub-pixel, the emission area EA-RG can be corresponding to the width of the emissive layer 142.

That is, the emission area EA-B in the blue sub-pixel is expanded by the width W of the anti-reflection pattern 152 compared to the emission area EA-RG in the red and green sub-pixels in accordance with the first embodiment.

In an organic light emitting diode, the red emitter (dopant) and the green emitter use phosphorescent materials, while the blue emitter uses fluorescent materials. Unlike the fluorescent materials that can utilize only singlet exciton energy, the phosphorescent materials that can utilize both singlet exciton energy and triplet exciton energy have relatively excellent luminous efficiency.

In a conventional display device, the luminous efficiency in the blue sub-pixel is lower than the luminous efficiency in the red sub-pixel and the green sub-pixel. In the conventional display device, it is difficult to implement a uniform white color since the luminous efficiency is different in each sub-pixel region.

On the other hand, the emission area EA-B in the blue sub-pixel is extended by the width W of the anti-reflection pattern 152 compared to the emission area EA-RG in the red sub-pixel and the green sub-pixel in accordance with the present disclosure. As the emission area EA-B is expanded in the blue sub-pixel with relatively low luminous efficiency, the amount of light transmitted to the display surface in the blue sub-pixel increases than the amount of light transmitted to the display surface in the red sub-pixel and the green sub-pixel. The intensity of light transmitted to the display surface in the blue sub-pixel with relatively low luminous efficiency is close to the intensity of light transmitted to the display surface in the red sub-pixel and the green sub-pixel. In accordance with the first embodiment, as the anti-reflection pattern 152 including the blue colorant 153c (FIG. 3) is disposed between the light emitting diode D and the bank layer 150, it is possible to implement the display device 100 having a uniform intensity of light in each sub-pixel region.

FIGS. 7 to 9 are schematic cross-sectional view illustrating arrangements of the light emitting diode, the anti-reflection pattern and the bank layer in the display device in accordance with other embodiments of the present disclosure.

In a display device 100A illustrated in FIG. 7, the anti-reflection pattern 152 disposed between the bank layer 150 and the emissive layer 142 covers a portion of the first electrode 140, for example, the periphery area of the first electrode 140. However, the bank layer 150 is disposed at an outside of the first electrode 140 without covering the first electrode 140. The light emitted from the emissive layer 142 can pass through the anti-reflection pattern 152 which is disposed to cover the periphery area of the first electrode 140. Since the bank layer 150 that absorbs and blocks the light emitted from the emissive layer 142 is disposed at the outside of the first electrode 140, the emission area EA can be further expanded.

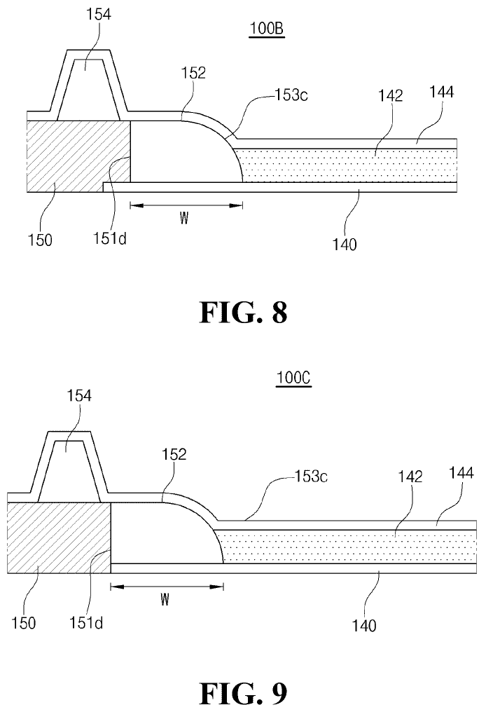

Compared to the configuration in FIG. 3, in a display device 100B illustrated in FIG. 8, the side surface 151d of the bank layer 150, which is in contact with the other side of the anti-reflection pattern 152, is disposed perpendicular to the upper surface of the first electrode 140. The upper portion of the bank layer 150 where the external light incidents has the same surface area as the lower portion of the bank layer 150. The external light incident on the bank layer 150 can be efficiently blocked and absorbed.

In a display device 100C illustrated in FIG. 9, the anti-reflection pattern 152 disposed between the bank layer 150 and the emissive layer 142 coves a portion of the first electrode 140, for example, the periphery area of the first electrode 140. However, the bank layer 150 is disposed at an outside of the first electrode 140 without covering the first electrode 140. The side surface 151d of the bank layer 150, which is in contact with the other side of the anti-reflection pattern 152, is disposed perpendicular to the upper surface of the first electrode 140.

Similar to the configuration illustrated in FIG. 7, the light emitted from the emissive layer 142 can pass through the anti-reflection pattern 152 which is disposed to cover the periphery area of the first electrode 140. Since the bank layer 150 that absorbs and blocks the light emitted from the emissive layer 142 is disposed at the outside of the first electrode 140, the emission area EA can be further expanded.

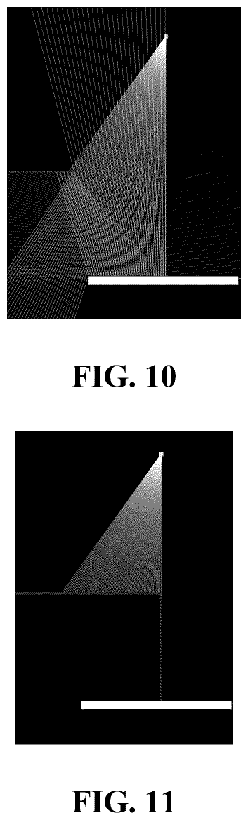

FIGS. 10 to 12 are simulation results illustrating a reflectance of external light by modification of an internal structure of the bank layer.

Referring to FIG. 10, when the side surface of the bank layer is configured to have a tapered cross-sectional shape, the surface area of the upper portion of the bank layer is reduced compared to the surface area of the lower portion of the bank layer. When the external light incidents on the bank layer, it can be seen that considerable reflection of the external light has occurred.

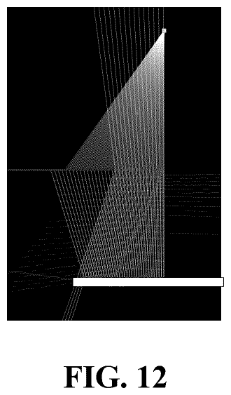

On the contrary, when the side surface of the bank layer is disposed perpendicular to the upper surface of the first electrode as illustrated in FIG. 11 or the side surface of the bank layer is disposed with a reverse cross-sectional tapered shape as illustrated in FIG. 12, the surface area of the upper portion of the bank layer increases. When the external light incidents on the bank layer, the reflection of the external light is greatly reduced as the external light is efficiently absorbed and blocked in the upper portion of the bank layer with a wide surface area.

In accordance with the first embodiment of the present disclosure, it is possible to manufacture a display device implementing ESG by improving the reliability of the bank layer and proving advantages of low-reflection and low-power.

### Second Embodiment

FIG. 13 illustrates a schematic cross-sectional view of the display device in accordance with a second embodiment of the present disclosure.

Referring to FIG. 13, a display device 200 in accordance with the second embodiment includes a substrate 202 having the emission area EA and the non-emission area NEA, a thin film transistor Tr, a light emitting diode D and a bank layer 250 disposed on the substrate 202, a column spacer 254 disposed on the bank layer 250, and a color filter layer 280 disposed on the light emitting diode D.

A pixel region P (FIG. 1) including the red sub-pixel, the green sub-pixel, the blue sub-pixel, and optionally, the white sub-pixel is defined in the substrate 202.

The thin film transistor Tr is disposed on the substrate 202. The thin film transistor Tr includes a semiconductor layer 210, a gate electrode 214, a source electrode 230, and a drain electrode 232. The thin film transistor Tr may be the driving thin film transistor Td (FIG. 1).

The thin film transistor Tr can be disposed directly on the substrate 202, or can be disposed on a first buffer layer that can be disposed on the substrate 202. A gate insulating layer 212 can be disposed on the semiconductor layer 210 with covering the entire substrate 202. The gate electrode 214 of a conductive material is disposed on the gate insulating layer 212 corresponding to the center of the semiconductor layer 210. The gate insulating layer 212 may be patterned as same as the gate electrode 214.

An interlayer insulting layer 220 is disposed on the gate electrode 214 with covering the entire substrate 202. The interlay insulating layer 220 may have first and second semiconductor contact holes 222 and 224 exposing both sides of the semiconductor layer 210. The first and second semiconductor contact holes 222 and 224 may be positioned to be spaced apart from the gate electrode 214 at both sides of the gate electrode 214.

The source electrode 230 and the drain electrode 232 of a conductive material such as metal are disposed on the interlayer insulating layer 220. The source electrode 230 and the drain electrode 232 are positioned to be spaced apart from each other with respect to the gate electrode 214 and contact both sides of the semiconductor layer 210 through the first and second semiconductor contact holes 222 and 224.

A planarization layer 234 is disposed on the source electrode 230 and the drain electrode 232 with covering the entire substrate 202. The planarization layer 234 has a drain contact hole 236 exposing the drain electrode 232 of the thin film transistor Tr.

The light emitting diode D includes a first electrode 240 disposed on the planarization layer 234 and connected to the drain electrode 232 of the thin film transistor Tr, and an emissive layer 242 and a second electrode 244 which are laminated sequentially on the first electrode 240.

A bank layer 250 covering a periphery area of the first electrode 240 is disposed on the planarization layer 234. In accordance with the second embodiment, the display device 200 comprises a column spacer 254 disposed to extend to an area between the bank layer 250 and the emissive layer 242 from the upper surface of the bank layer 250. It is possible to minimize stains caused by the reflection of external light and to expand the emission area EA by applying the column spacer 254.

The column spacer 254 can comprise a body component 256 disposed on the bank layer 250. In one embodiment, the body component 256 can have a cross-sectional shape of which the width gradually increases toward the bank layer 250 (a trapezoidal cross-sectional shape or a tapered cross-sectional shape), or a cross-sectional shape of which the width gradually decreases toward the bank layer 250 (an inverted-trapezoidal cross-sectional shape or a revere tapered cross-sectional shape), but is not limited thereto.

An encapsulation layer (encapsulation film) 260 is disposed on the second electrode 244 in order to prevent external oxygen and/or moisture form infiltrating to the light emitting diode D. The encapsulation layer 260 can have a lamination structure of a first inorganic insulating layer 262, an organic insulating layer 264 and a second inorganic insulating layer 264, but is not limited thereto.

A touch sensor 270 including a connection electrode 272, a first touch insulating layer 274a, a second touch insulating layer 274b, a first touch electrode 276 and a second touch electrode 278 can be disposed on the encapsulation layer 260. In some embodiments, the touch sensor 270 may be omitted.

A black matrix 280 and a color filter layer 282 are disposed on the encapsulation layer 260 or the second touch insulating layer 274b. A first insulating layer 290 can be disposed on the color filter layer 282. Alternatively or additionally, a second insulating layer can be disposed on the first insulating layer 290.

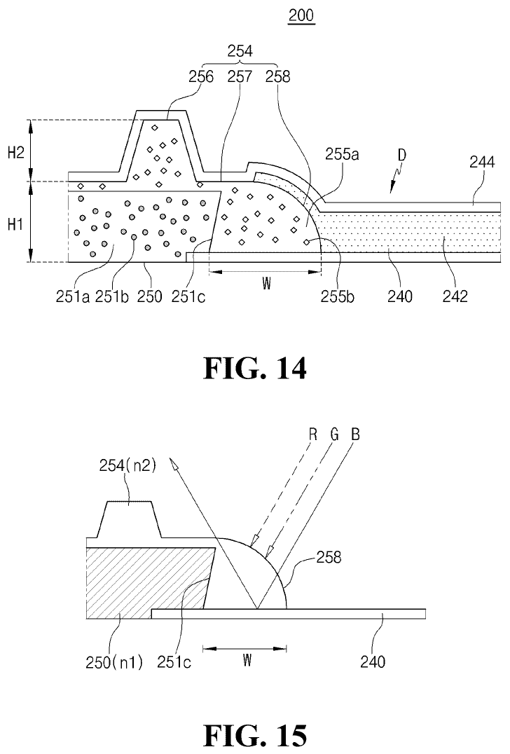

The structure and arrangements of the light emitting diode, the bank layer and the column spacer in accordance with the second embodiment will be described in more detail. FIG. 14 is a schematic diagram illustrating components of a light emitting diode, a bank layer and a column spacer in the display device in accordance with the second embodiment of the present disclosure.

Referring to FIG. 14, the bank layer 250 is disposed to be spaced apart from a side of the emissive layer 242 constituting the light emitting diode D. The column spacer 254 is disposed to extend to the area between the emissive layer 242 of the light emitting diode D and the bank layer 250 from the upper surface of the bank layer 250.

In one embodiment, the column spacer 250 can include the body component 256 disposed to protruded upwardly from the upper surface of the bank layer 250, a connecting or extending component 257 extending horizontally toward the light emitting diode D from the body component 256, and an inclined component 258 having a cross-sectional shape inclined downwardly from the connecting component 257. As an example, the bank layer 250 and the inclined component 258 of the column spacer 254 can be disposed to cover a portion of the first electrode 240, for example, the periphery area of the first electrode 240.

The bank layer 250 can comprise a first photosensitive binder resin 251a and a light-blocking material 251b. The column spacer 254 can comprise a second photosensitive binder resin 255a and a blue colorant 255b. For example, each of the first photosensitive binder resin 251a and the second photosensitive binder resin 255a can independently comprise, but is not limited to, an acryl-containing binder resin, a methacyl-containing binder resin, an acrylamide-containing binder resin, an imide-containing binder resin, an epoxy-containing binder resin, a cardo-containing binder resin, a fluorene-containing binder resin, a siloxane-containing binder resin, copolymers thereof or combinations thereof.

The light-blocking material 251b in the bank layer 250 may be the same as the light-blocking material 151b in the bank layer 150 described in the first embodiment. The blue colorant 255b in the column spacer 254 may be the same as the blue colorant 153b in the anti-reflection pattern 152 described in the first embodiment. The connecting component 257 and/or the inclined component 258 of the column spacer 254 including the blue colorant 255b are disposed between the light emitting diode D and the bank layer 250, for example, between the emissive layer 242 and the bank layer 250. Accordingly, it is possible to minimize the reflection of external light and expand the emission area EA in the display device 200.

In one embodiment, a height H1 of the bank layer 250 and/or the inclined component 258 of the column spacer 254, and a height H2 of the body component 256 of the column spacer 254 can be, but is not limited to, about 1 μm to about 3 μm. In another embodiment, a width W of the inclined component 258 of the column spacer 254 disposed between the light emitting diode D and the bank layer 250 can be, but is not limited to, about 0.5 μm to about 3 μm, for example, about 0.5 μm to about 2 μm. For example, the column spacer 254 can be disposed on the first electrode 240 and the bank layer 250 by performing a negative photoresist process using a full-tone mask, but is not limited thereto.

In one exemplary embodiment, the inclined component 258 of the column spacer 254, which is in contact with or facing a side of the emissive layer 242 of the light emitting diode D, can have a cross-sectional shape inclined downwardly toward the light emitting diode D, for example, the emissive layer 242. For example, the inclined component 258 of the column spacer 254 can have a cross-sectional shape of which the width gradually increases toward the first electrode 240, or a tapered cross-sectional shape, but is not limited thereto.

The inclined component 258 of the column spacer 254 may be curved with a predetermined curvature, or may extend downwardly without the curvature. For example, the inclined component 258 of the column spacer 254 can be disposed with an angle of about 30° to about 60° with respect to the first electrode 240, but is not limited thereto. As the inclined component 258 of the column spacer 254 has the tapered cross-sectional shape, the occurrence of a dead point in the light emitting diode can be minimized, and disconnection or lifting in the light emitting diode D can be prevented.

In another embodiment, a side surface 251c of the bank layer 250, which is in contact with the other side surface of the inclined component 258 disposed between the emissive layer 242 and the bank layer 250 among the column spacer 254, can have a cross-sectional shape inclined downwardly toward an opposite side of the inclined component 258. In other words, with respect to the bank layer 250, the side surface 251c of the bank layer 250 can have a cross-sectional shape of which the width gradually decreases toward the first electrode 240, or a reverse tapered cross-sectional shape. For example, the side surface 251c of the bank layer 250 can be disposed with an angle greater than 90° and equal to or less than 150° with respect to the first electrode 240, but is not limited thereto. In one embodiment, as the side surface 251c of the bank layer 250 has the reverse tapered cross-sectional shape, the absorption and blocking of the external light in the bank layer 250 can be improved.

FIG. 15 is a schematic diagram illustrating that the external light reflection is minimized in the display device in accordance with the second embodiment of the present disclosure.

Referring to FIG. 15, all the red light R, the green light G and the blue light B which are the light in the visible region among the external light are absorbed and blocked in the bank layer 250 including the light-blocking material 251b (FIG. 14). Accordingly, reflection of external light can be minimized and stains caused by the reflection of external light can be prevented.

In addition, the red light R and the green light G among the external light are absorbed and blocked by the column spacer 254, for example, the inclined component 258 including the blue colorant 255b (FIG. 14). On the contrary, the blue light B incident on the column spacer 254 transmits or passes through the column spacer 254, and some of the blue light B is reflected from the first electrode 240.

The red light R and the green light G, which are relatively clearly recognized by the human eyes, among the external light are blocked by the column spacer 254 including the blue colorant 255b (FIG. 14) and are not reflected to the outside. The red light R and the green light G, which are relatively easily recognized by the human eye, among the external light are absorbed and blocked by the column spacer 254. Reflection of external light corresponding to the wavelength bands of the red light R and the green light G is not recognized.

In one embodiment, the bank layer 250 can have a first refractive index n1 equal to or more than a second refractive index n2 of the column spacer 254. When the external light passing through the column spacer 254, which is a relatively less dense medium, is incident on the bank layer 250, which is a relatively dense medium, it is refracted to the bank layer 250 without total reflection. And then, the external light incident on the bank layer 250 can be efficiently absorbed and blocked by the bank layer 250 including the light-blocking material 251b (FIG. 14). For example, the first refractive index n1 of the bank layer 250 can be about 1.6 to about 1.9, and the second refractive index n2 of the column spacer 254 can be about 1.5 to about 1.8, but is not limited thereto.

Similar to the first embodiment, the column spacer 254 including the blue colorant 255b is disposed between the emissive layer 242 of the light emitting diode D and the bank layer 250. The blue light B among the light emitted from the emissive layer 242 passes through the column spacer 254 and transmits to the display surface. Accordingly, the emission area EA can be expanded by the width W of the inclined component 258 of the column spacer 254 disposed between the emissive layer 242 and the bank layer 250.

Similar to the first embodiment, the emission area EA-B in the blue sub-pixel can be further expanded by the width W of the inclined component 258 compared to the emission area EA-RG in the red sub-pixel and the green sub-pixel (FIGS. 6A and 6B). As the emission area EA-B is expanded in the blue sub-pixel with relatively low luminous efficiency, the amount of light transmitted to the display surface in the blue sub-pixel increases than the amount of light transmitted to the display surface in the red sub-pixel and the green sub-pixel.

The intensity of light transmitted to the display surface in the blue sub-pixel with relatively low luminous efficiency is close to the intensity of light transmitted to the display surface in the red sub-pixel and the green sub-pixel. In accordance with the second embodiment, as the column spacer 254 including the blue colorant 255b (FIG. 14) is disposed between the light emitting diode D and the bank layer 250, it is possible to implement the display device 200 having a uniform intensity of light in each sub-pixel region.

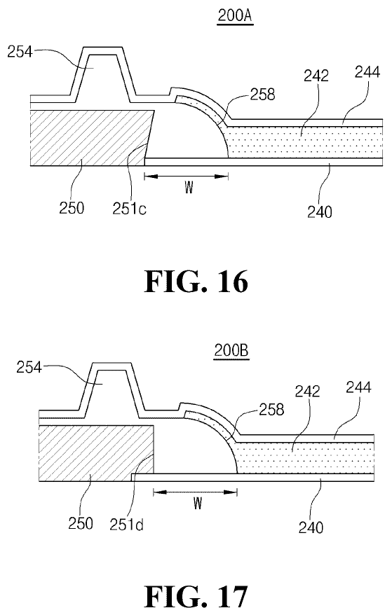

FIGS. 16 to 18 are schematic cross-sectional view illustrating arrangements of the light emitting diode, the bank layer and the column spacer in the display device in accordance with other embodiments of the present disclosure.

In a display device 200A illustrated in FIG. 16, the inclined component 258 of the column spacer 254 disposed between the bank layer 250 and the emissive layer 242 covers a portion of the first electrode 240, for example, the periphery area of the first electrode 240. However, the bank layer 250 is disposed at an outside of the first electrode 240 without covering the first electrode 240. The light emitted from the emissive layer 242 can pass through the column spacer 254 which is disposed to cover the periphery area of the first electrode 240. Since the bank layer 250 that absorbs and blocks the light emitted from the emissive layer 242 is disposed at the outside of the first electrode 240, the emission area EA can be further expanded.

Compared to the configuration in FIG. 14, in a display device 200B illustrated in FIG. 17, the side surface 251d of the bank layer 250, which is in contact with the other side surface of the inclined component 258 of the column spacer 254, is disposed perpendicular to the upper surface of the first electrode 240. The upper portion of the bank layer 250 where the external light incidents has the same surface area as the lower portion of the bank layer 250. The external light incident on the bank layer 250 can be efficiently blocked and absorbed.

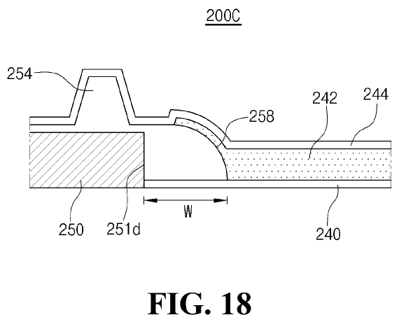

In a display device 200C illustrated in FIG. 18, the column spacer 254, for example, the inclined component 258, disposed between the bank layer 250 and the emissive layer 242 coves a portion of the first electrode 240, for example, the periphery area of the first electrode 240. However, the bank layer 250 is disposed at an outside of the first electrode 240 without covering the first electrode 240. The side surface 251d of the bank layer 250, which is in contact with the other side surface of the inclined component 258, is disposed perpendicular to the upper surface of the first electrode 240.

Similar to the configuration illustrated in FIG. 16, the light emitted from the emissive layer 242 can pass through the inclined component 258 of the column spacer 254 which is disposed to cover the periphery area of the first electrode 240. Since the bank layer 250 that absorbs and blocks the light emitted from the emissive layer 242 is disposed at the outside of the first electrode 240, the emission area EA can be further expanded.

In accordance with the second embodiment, the stains caused by the reflection of external light can be minimized, and the reliability of the black bank layer can be improved with maintaining sufficient optical density of the black bank layer. In addition, ESG can be implemented by proving the advantage of low reflection and low power.

### Third Embodiment

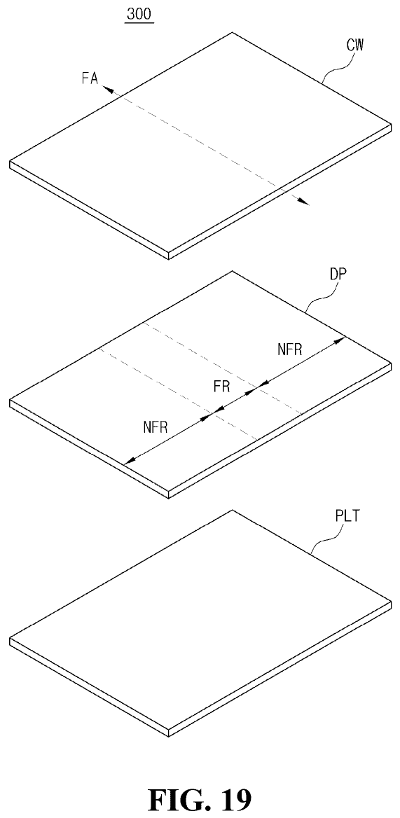

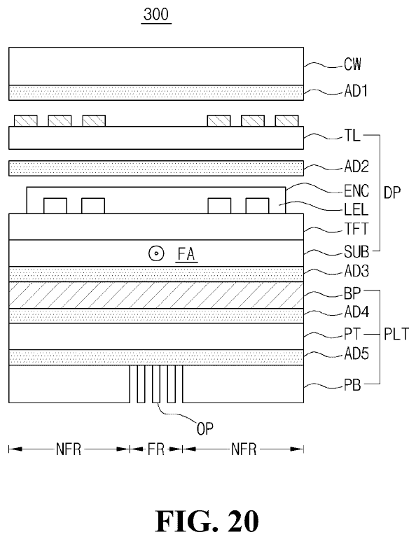

The display device in accordance with the present disclosure may be a foldable display device. FIG. 19 illustrates a schematic exploded perspective view of a display device in accordance with a third embodiment of the present disclosure. FIG. 20 illustrates a schematic cross-sectional view of the display device in accordance with the third embodiment of the present disclosure.

Referring to FIGS. 19 and 20, a display device 300 includes a folding region FR and a non-folding region NFR, and can be folded along a first direction. The display device 300 may comprise the non-folding region NFR at both sides of the folding region FR along the first direction.

The display device 300 may be out-folded in which the display surface is exposed to the outside when implementing the folding state, but is not limited thereto. Alternatively or additionally, the display device 30 may be in-folded in which the display surface is hidden therein.

In one embodiment, a display panel DP may be folded inwardly or outwardly with respect to a folding axis FA. In the present disclosure, the folding axis FA represents a center of the folding area having a predetermined curvature due to folding by an imaginary line. While the display panel DP is illustrated to be folded at a center portion in FIG. 19, the entire portion of the display panel DP may be freely deformed.

The display panel DP may include a substrate SUB including a flexible material so that the display area may be folded inwardly or outwardly, and an element layer for displaying an image. For example, the element layer may include a thin film transistor element layer TFT and a light emitting element layer LEL disposed in the display area on the substrate SUB.

An encapsulation layer ENC is disposed on the light emitting element layer LEL, a touch layer (touch sensor) TL is disposed on the encapsulation layer ENC, and a cover window CW is disposed on the touch layer TL. In addition, a color filter layer and/or a black matrix may be disposed on the touch layer TL, for example, between the touch layer TL and the cover window CW.

A plate PLT is disposed on the lower surface of the substrate SUB for supporting the substrate SUB. For example, the plate PLT may comprise a back plate BP, a plate top PT and a plate bottom PB disposed sequentially on the lower surface of the substrate SUB.

The thin film transistor element layer TFT includes a thin film transistor with a semiconductor layer, a gate electrode, a source electrode and a drain electrode, a gate insulating layer and an interlayer insulating layer. The thin film transistor may have the structure illustrated in FIG. 2 or FIG. 13. The thin film transistor may be a driving thin film transistor and may comprise an oxide semiconductor.

The light emitting element layer LEL may comprise a light emitting diode, a bank layer, an anti-reflection pattern and/or a column spacer. The arrangements and/or shapes of the light emitting diode, the bank layer, the anti-reflection pattern and/or the column spacer may be the same referring to FIGS. 2 to 10 and/or FIGS. 13 to 18.

The substrate SUB on which the thin film transistor element layer TFT and the light emitting element layer LEL are disposed may be encapsulated by the encapsulation layer ENC. The encapsulation layer ENC prevents external oxygen and/or moisture from infiltrating to the light emitting element layer LEL.

The cover window CW constitutes an outer periphery of the display device 300. The cover window CW may be positioned outside the surface on which the image is displayed on the display panel DP, transmits the images of the display panel DP, and protects the display panel DP from external impact or stress.

The cover window CW may comprise a reinforced glass and/or a reinforced plastic material. For example, the cover window CW may include, but is not limited to, a material selected from high-strength reinforced glass, polyethylene terephthalate (PET), acrylic resins and/or (meth) acrylate resins such as polymethyl methacrylate (PMMA) to prevent scratches form the outside.

The back plate BP may comprise an organic material with beneficial folding properties. For example, the back plate BP can comprise, but is not limited to, a polyimide (PI).

The plate top PT and the plate bottom PB may comprise a metal component, and the thickness of the plate bottom PB exposed to the outside may be larger than the thickness of the plate top PT. For example, the plate top PT may comprise SUS301 with relatively high hardness and the plate bottom PB may comprise SUS313 with higher corrosion resistance and acid resistance, but is not limited thereto.

The plate bottom PB comprises a plurality of openings OP in the folding area FR so that the display device 300 can improve the folding property. In one embodiment, the plurality of openings OP may be configured to penetrate the surface and/or rear surface of the plate bottom PB.

A plurality of adhesive components AD1, AD2, AD3, AD4 and AD5 may be disposed among the plurality of components in the display device 300. For example, a first adhesive component AD1 may be disposed between the touch layer TL and the cover window CW, a second adhesive component AD2 may be disposed between the encapsulation layer ENC and the touch layer TL, a third adhesive component AD3 may be disposed between the substrate SUB and the back plate BP, a fourth adhesive component AD4 may be disposed between the back plate BP and the plate top PT, and a fifth adhesive component AD5 may be disposed between the plate top PT and the plate bottom PB. Each of the first to fifth adhesive components AD1, AD2, AD3, AD4 and AD5 may comprise an optically clear adhesive (OCA) and/or a pressure sensitive adhesive (PSA).

In accordance with the third embodiment, it is possible to minimize the stains caused by the reflection of external light, and to implement the display device with beneficial luminous efficiency. In addition, the foldable display device with beneficial flexibility by omitting a polarizer may be fabricated. The display device implementing ESG can be manufactured with the advantages of low reflection and low power.

It will be apparent to those skilled in the art that various modifications and variations can be made in the present disclosure without departing from the scope of the disclosure. Thus, it is intended that the present disclosure cover the modifications and variations of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate having an emission area and a non-emission area;
a light emitting diode disposed on the substrate in alignment with the emission area;
a bank layer disposed on the substrate in alignment with the non-emission area; and
an anti-reflection pattern disposed between the light emitting diode and the bank layer, and comprising a blue colorant,
wherein the light emitting diode comprises a first electrode, a second electrode facing the first electrode, and an emissive layer disposed between the first electrode and the second electrode.

2. The display device of claim 1, wherein a side surface of the anti-reflection pattern that faces the emissive layer has a cross-sectional shape that is inclined downwardly toward the emissive layer.

3. The display device of claim 1, wherein a side surface of the bank layer that faces the anti-reflection pattern has a cross-sectional shape inclined downwardly and away from the anti-reflection pattern.

4. The display device of claim 1, wherein a side surface of the bank layer that faces the anti-reflection pattern, is disposed perpendicular to a surface of the first electrode.

5. The display device of claim 1, wherein the display device further comprises a column spacer disposed on the bank layer.

6. The display device of claim 5, wherein the column spacer comprises a blue colorant.

7. The display device of claim 1, wherein the anti-reflection pattern and the bank layer are each disposed to cover a portion of a surface of the first electrode.

8. The display device of claim 1, wherein the anti-reflection pattern is disposed to cover a portion of the first electrode and the bank layer is disposed at an outside of the first electrode.

9. The display device of claim 1, wherein the bank layer has a refractive index equal to or more than a refractive index of the anti-reflection pattern.

10. The display device of claim 1, wherein the bank layer comprises a black colorant.

11. The display device of claim 1, wherein the bank layer comprises a material that blocks light or absorbs light.

12. The display device of claim 1, wherein the display device further comprises:
a driving thin film transistor disposed on the substrate and connected to the light emitting diode and comprising an oxide semiconductor;
an encapsulation layer disposed on the second electrode; and
a color filter layer disposed on the encapsulation layer, and
wherein the bank layer comprises a black colorant.

13. A display device, comprising:
a substrate having an emission area and a non-emission area;
a light emitting diode disposed on the substrate in alignment with the emission area;
a bank layer disposed on the substrate in alignment with the non-emission area; and
a column spacer extending from an upper surface of the bank layer to an area between the light emitting diode and the bank layer, and comprising a blue colorant,
wherein the light emitting diode comprises a first electrode, a second electrode facing the first electrode, and an emissive layer disposed between the first electrode and the second electrode.

14. The display device of claim 13, wherein a side surface of the column spacer that faces the emissive layer has a cross-sectional shape that is inclined downwardly toward the emissive layer.

15. The display device of claim 13, wherein the column spacer comprises:
a body component disposed on the bank layer;
a connecting component that extends toward the light emitting diode from the body component; and
an inclined component having a cross-sectional shape inclined downwardly from the connecting component, and
wherein the inclined component is disposed between the bank layer and the emissive layer.

16. The display device of claim 15, wherein a side surface of the bank layer, which is in contact with the inclined component of the column spacer, has a cross-sectional shape inclined downwardly toward an opposite side of the inclined component of the column spacer.

17. The display device of claim 15, wherein a side surface of the bank layer, which is in contact with the inclined component of the column spacer, is disposed perpendicular to a surface of the first electrode.

18. The display device of claim 15, wherein the inclined component of the column spacer and the bank layer are disposed to cover a portion of a surface of the first electrode.

19. The display device of claim 15, wherein the inclined component is disposed to cover a portion of a surface of the first electrode and the bank layer is disposed at an outside of the first electrode.

20. The display device of claim 13, wherein the column spacer has a refractive index equal to or more than a refractive index of the bank layer.
